(19) United States
(12) Patent Application Publication
(10) Pub. No.: US 2024/0156058 A1
(43) Pub. Date: May 16, 2024

(54) ELECTRICAL STIMULUS CIRCUIT

(71) Applicant: HALTER USA INC., San Francisco, CA (US)

(72) Inventor: Masoud SARGAZIKOOSHEH, Auckland (NZ)

(73) Assignee: HALTER USA INC., San Francisco, CA (US)

(21) Appl. No.: 18/512,929

(22) Filed: Nov. 17, 2023

Related U.S. Application Data
(63) Continuation-in-part of application No. PCT/IB2022/054822, filed on May 24, 2022.

(30) Foreign Application Priority Data
May 26, 2021 (AU) 2021901583
Aug. 24, 2021 (AU) 2021221500

(51) Int. Cl. A01K 15/04

(52) U.S. Cl. CPC A01K 15/04

(57) ABSTRACT

The present invention relates to a remotely triggered improved electrical stimulus circuit to be worn by cattle that is lightweight and can store voltage lower than what is to be supplied to an animal. Known cattle electrical stimulus collars may be heavy, use a lot of energy, and not supply a consistent electrical stimulus. The present electrical stimulus circuit utilizes feedback loops to allow the use of high tolerance lightweight capacitors, and/or cool down periods to utilize a highly inefficient transformer running fully saturated.

### CROSS-REFERENCE TO RELATED APPLICATIONS

This application is a Continuation-in-Part application of PCT/IB2022/054822, filed May 24, 2022, and claims priority to Australian Patent Application No. 2021901583, which was filed May 26, 2021 and to Australian Patent Application No. 2021221500, which was filed Aug. 24, 2021. Each of these priority applications is incorporated herein by reference in their entirety.

### TECHNICAL FIELD

The present invention relates to an improved electrical stimulus circuit. More particularly but not exclusively, it relates to a remotely triggerable improved electrical stimulus circuit for a wearable device to be worn by cattle which is very lightweight due to using underrated transformers and capacitors.

### BACKGROUND OF THE INVENTION

Electrical stimulus collars have been used on pets, such as dogs, for many years. The electrical stimulus collar may be activated by a user trigger, by a physical boundary such as a buried wire, or by a virtual boundary. Typically, electrical stimulus collars only supply enough energy to give an aversive stimulus to a dog. The voltage of an electrical stimulus collar can vary from model to model. However, the typical range on an electrical stimulus collar may be between 400 to 1000 volts. The electrical stimulus collar needs to be lightweight so it can be carried by an animal, and be energy efficient so the batteries are not drained too quickly.

Fence energisers are the best analogy for the current invention as they try to achieve the same outcome of supplying an electrical stimulus to a large animal. Electric fences are typically used to keep cattle (e.g. cows) confined to a zone. Electric fence energisers supply energy through fence wire, through the cow, to return to an earth electrode near the energiser. The power supply, or electric fence energiser, typically outputs 2000 to 12000 volts depending on the fencing configuration, animal type and other factors. This voltage is larger compared to dog electrical stimulus collars, as the voltage is required to either make the energy jump from the fence to the cow and also across the sometimes thick coat of a cow. An electric fence energizer has very low amperage or current, around 120 milliamps. This is made safer again in two ways, firstly by releasing the flow of electrons from the electric fence energizer in regular pulses of high voltage but very low amperage. Secondly, the electrical energy pulses through the wires. This means once every second for 3/10,000th of a second it sends a pulse of electricity down the line. The reason for the pulsating current is that if the wires are touched and deliver an electrical stimulus, whatever touches it has a chance to remove itself.

To achieve the above characteristics, an electric fence energizer is typically mains powered, large, wall-mounted, and heavy. Solar power electric fence energizers are also available to be situated on the farm, away from mains power. These may have a large solar panel and a heavy battery mounted to a portable cart for ease of transport.

### OBJECT OF THE INVENTION

It is an object of the present invention to provide an electrical stimulus circuit that overcomes or at least partially ameliorates some of the abovementioned disadvantages or which at least provides the public with a useful choice.

### SUMMARY OF THE INVENTION

In a first aspect, the invention resides in an animal stimulus collar configured to be worn by an animal comprising an electrical stimulus system configured to apply an electrical stimulus to an animal, the system comprising:
an energy source;
an electrode pair positioned on the collar;
an electrical stimulus circuit operable to generate the electrical stimulus from the energy source, and provide the generated stimulus to the electrode pair;
a controller configured to operate the electrical stimulus circuit when required; and
wherein the electrical stimulus circuit comprises an output transformer, and is configured to generate the electrical stimulus from operation of the output transformer characterised by operational parameters representing a substantially saturated state.

In another aspect, the invention resides in an electrical stimulus system for a wearable device configured to be worn by an animal, the system configured to apply an electrical stimulus to an animal, the system comprising:
a. an energy source;
b. an electrode pair;
c. an electrical stimulus circuit operable to generate the electrical stimulus from the energy source, and provide the generated stimulus to the electrode pair;
d. a controller configured to operate the electrical stimulus circuit when required; and
wherein the electrical stimulus circuit comprises an output transformer, and the circuit is configured to generate the electrical stimulus from operation of the output transformer characterised by operational parameters representing a substantially saturated state.

In some embodiments, the output transformer operationally generates the electrical stimulus as an output pulse having an output pulse energy and an output pulse width, wherein operation of the output transformer is characterised by any one or more of the following operational parameters:
up to 90% of the output pulse energy is generated by the output transformer operating in a saturated state;
up to 85% of the output pulse energy is generated by the output transformer operating in a saturated state;
up to 80, 75, 70, 65, 60, 55, 50, 45, 40, 35, or 30% of the output pulse energy is generated by the output transformer operating in a saturated state;
the output pulse energy is up to 50% of the pulse energy input to the output transformer;
the output pulse energy is up to 20, 25, 30, 35, 40, 45, 50, or 55% of a pulse energy input into to the output transformer;
the output pulse energy is substantially 0.15 J and a pulse energy input into the output transformer is substantially 0.5 J;
the output pulse energy is substantially 0.15 J and a input pulse energy input into to the output transformer is at least 0.4, 0.45, 0.5, 0.55, 0.6, 0.65, 0.7, 0.75, 0.8, 0.85, 0.9 or 0.95 J;
at least 50% of the output pulse width is generated by the output transformer operating with an efficiency of 50% or less;
at least 55, 60, 65, 70, 75, 80, 85, 90 or 95% of the output pulse width is generated by the output transformer operating with an efficiency of 50% or less;
a primary winding of the output transformer receives about 60-80 A, and a secondary winding of the output transformer outputs about 3 A.

In some embodiments, the circuit further comprises a boost transformer configured to receive energy directly or indirectly from the energy source and step up the voltage of the energy source.

In some embodiments, the circuit further comprises a capacitor circuit comprising one or more capacitors configured to store energy from the boost transformer at the voltage supplied by the boost transformer.

In some embodiments, the output transformer is configured to receive energy stored by the capacitor circuit.

In some embodiments, the output transformer comprises a second transformer and the system further comprises a first transformer, and the controller is configured to:
control the connection of the energy source to the first transformer during a first interval;
control the connection of the capacitor circuit to the first transformer during the first interval to store energy from the first transformer;
control the connection of the capacitor circuit to the second/output transformer during a second interval; and
control the connection of the electrode pair to the second transformer during the second interval to realise operation of the substantially saturated state.

In some embodiments, the connection of at least the second interval comprises a pulsed connection to thereby elicit flyback operation in the second transformer.

In some embodiments, the output transformer is configured to step up the energy stored by the capacitor circuit to a range between 400V and 30 kV.

In some embodiments, the energy source supplies between 20 and 40 watts, and/or 3 and 5 volts, or about 4.2 volts.

In some embodiments, the boost transformer increases the energy source volts to a range between 400 volts and 800 volts.

In some embodiments, the boost transformer increases the energy source volts to a range between 500 and 700 volts.

In some embodiments, the boost transformer increases the energy source volts to 600 volts.

In some embodiments, the boost transformer operates in the linear region of saturation.

In some embodiments, the output transformer is less than 27 cm3 in volume.

In some embodiments, the output transformer is less than 40 mm×40 mm in width and depth.

In some embodiments, the output transformer is less than 30 mm×30 mm in width and depth.

In some embodiments, the output transformer is less than 40 mm, less than 30 mm, or less than 20 mm in height excluding its legs.

In some embodiments, the output transformer is 17 mm in height, excluding the legs.

In some embodiments, the output transformer is cuboid in shape.

In some embodiments, the capacitor circuit comprises at least a first and second capacitor.

In some embodiments, the controller is configured to control charging of the capacitor circuit.

In some embodiments, the controller is configured to control the discharge of the one or more capacitors in the capacitor circuit to thereby control a voltage profile of a discharge voltage pulse.

In some embodiments, the controller is configured to control the discharge timing of one or more capacitors in the capacitor circuit to thereby control at least one of amplitude, wavelength, and frequency of the voltage pulse.

In some embodiments, the voltage pulse is stepped up by the output transformer to generate the output pulse forming at least part of the electrical stimulus to be delivered to the animal.

In some embodiments, the electrical stimulus is delivered over an electrical stimulus time of 0.5 to 1.5 seconds.

In some embodiments, the electrical stimulus is delivered over an electrical stimulus period of 1 second.

In some embodiments, the plurality of voltage pulse is repeated between 2 and 6 pulses during the electrical stimulus time.

In some embodiments, the voltage pulse is repeated 3 times during the electrical stimulus time.

In some embodiments, the controller is configured to allow cooling of the capacitors (not charging or discharging) between voltage pulses.

In some embodiments, the controller is configured to operate the electrical stimulus circuit to generate multiple electrical stimulus, wherein the time between electrical stimulus is at least 3 seconds.

In some embodiments, the time between electrical stimulus is 10 seconds.

In some embodiments, the time between electrical stimulus is at least 3 seconds.

In some embodiments, the time between electrical stimulus is 10 seconds.

In some embodiments, the capacitors are electrolytic capacitors.

In some embodiments, the electrolytic capacitors are aluminium type.

In some embodiments, the capacitors are film capacitors.

In some embodiments, the capacitance of the capacitor circuit is between 3 and 20 uF.

In some embodiments, the capacitance of the capacitor circuit is 3.3 uF and 15 uF.

In some embodiments, the capacitance of the capacitor circuit is 10 uF.

In some embodiments, the electrical stimulus circuit comprises a capacitor feedback signal and the controller is further configured to determine the variables of the voltage pulse, so as allow the microcontroller to control one or more of:
the charge time and timing of the capacitor circuit;
the discharge time and discharge timing of the capacitor circuit;
a change to one or more of the voltage amplitude, current amplitude, period, and frequency of the voltage pulse; and/or
a change to the number of pulses within a duration of an electrical stimulus.

In some embodiments, the electrical stimulus circuit further comprises a feedback circuit generating a feedback signal indicative of electrode operation, and the controller is further configured to determine if the electrical stimulus is successfully applied to the animal based on the feedback signal.

In some embodiments, the feedback circuit comprises a shunt resistor configured between the electrode pair, and the feedback signal is indicative of the current flowing through the feedback resistor.

In some embodiments, the controller is configured to determine successful electrical stimulus delivery when the feedback signal is indicative of current above a predetermined threshold.

In some embodiments, the predetermined current threshold is between 2 and 6 Amps.

In some embodiments, the controller is configured to determine the current threshold has not been met, and in response, is configured to resend an electrical stimulus.

In some embodiments, the electrode pair comprises a positive and negative electrode spaced a distance apart, and are configured to receive part of an animal in between.

In some embodiments, the distance apart is between 50 mm and 300 mm.

In some embodiments, the distance apart is between 90 and 200 mm.

In some embodiments, each electrode is a strip electrode configured to complement a contour of the animal's neck.

In some embodiments, the positive electrode is located on the wearable device so as to be located on an opposing side of the animal's neck to the negative electrode.

In some embodiments, the at least one electrode of the electrode pair comprise a flush surface to lay against an animal in use.

In some embodiments, the distance apart is dependent on the width of the animal's neck.

In some embodiments, the electrodes are spaced offset from the skin of the animal.

In some embodiments, the electrodes sit on the hair of the animal.

In some embodiments, the electrical stimulus circuit is configured to supply an electrical stimulus capable of jumping the animal's hair.

In some embodiments, the electrode or electrodes are configured as pins or knobs.

In some embodiments, the controller is configured to operate the electrical stimulus circuit when only after a predetermined time period has elapsed.

In some embodiments, the controller is configured to allow only one pulse to be delivered at a time to an animal.

In some embodiments, the wearable device is a collar configured to locate at least partially about the animal's neck.

In some embodiments, the energy source is a battery.

In some embodiments, the battery is charged by solar panels.

In some embodiments, the system further comprises solar panels configured to charge the energy source.

In a further aspect, the invention resides in an electrical stimulus system for a wearable device configured to be worn by an animal, the system configured to apply an electrical stimulus to an animal, the system comprising:
a. an energy source to supply DC current energy,
b. an electrical stimulus circuit comprising
   i. an output transformer comprising a primary inductor electrically connected directly or indirectly the energy source; and a secondary inductor, the output transformer configured to increase the voltage of the energy source voltage, wherein the output transformer when charged is always fully saturated and
   ii. an electrode pair configured to transfer energy from the output transformer between them via an animal, at least one of the electrode pair electrically connected to the secondary inductor, and
c. a microcontroller configured for activating said electrical stimulus circuit to supply an electrical stimulus to the animal when required.

In some embodiments, the electrical stimulus circuit comprises
a boost transformer configured to receive energy directly or indirectly from the energy source and increase the voltage of the energy to a range between 400 volts and 800 volts (‘First transformer volts’), and
a capacitor circuit comprising one or more capacitors to store energy from the boost transformer at the voltage supplied by the transformer.

In some embodiments, the output transformer receives energy from the one or more capacitors.

In some embodiments, the output transformer increase the boost transformer voltage to a range between 1 kV and 30 kV (‘electrical stimulus voltage’).

In some embodiments, the energy source supplies power in a range between 20 and 40 watts, and/or 3 and 5 volts, preferably 4.2 volts.

In one embodiment, the first transformer increases the energy source volts to a range between 400 volts and 800 volts.

In some embodiments, the first transformer increases the energy source volts to a range between 500 and 700 volts.

In some embodiments, the first transformer increases the energy source volts to 600 volts.

In some embodiments, the microcontroller is configured to one or more of; control energy delivered to the electrical stimulus circuit; receive feedback from the electrical stimulus circuit; and receive instructions from a microcontroller.

In some embodiments, the capacitor circuit comprises at least a first and second capacitor.

In some embodiments, the microcontroller directly or indirectly controls the charge and discharge, to form a capacitor pulse, of the capacitor circuit.

In some embodiments, the plurality of capacitor pulses are stepped up by the output transformer to a plurality of electrical stimulus pulses forming the electrical stimulus to be delivered to the animal.

In some embodiments, the electrical stimulus is delivered over an electrical stimulus time of 0.5 to 1.5 seconds.

In some embodiments, the electrical stimulus is delivered over an electrical stimulus period of 1 second.

In some embodiments, the plurality of capacitor pulses is between 2 and 6 pulses.

In some embodiments, the plurality of capacitor pulses is 3 pulses.

In some embodiments, the number of electrical stimulus pulses is the same as the capacitor pulses.

In some embodiments, the amplitude, wavelength, and frequency of the capacitor pulse is controlled by the microcontroller.

In some embodiments, the capacitors cool down between electrical stimuli, and/or the capacitors cool down between capacitor pulses.

In some embodiments, the time between electrical stimuli is greater than 3 seconds, and preferably 10 seconds.

In some embodiments, the capacitors are electrolytic capacitors.

In some embodiments, electrolytic capacitors are aluminium type.

In some embodiments, the capacitor circuit comprises up to six additional capacitors.

In some embodiments, the electrical stimulus circuit comprises additional capacitor circuits, each additional capacitor circuit comprising one or more capacitors.

In some embodiments, each additional capacitor circuit is individually controllable to electrically ‘connect’ it to the electrical stimulus circuit.

In some embodiments, an additional capacitor circuit when turned on (to electrically connect to the electrical stimulus circuit) increases the storage of energy (capacitance) in the electrical stimulus circuit.

In some embodiments, one or more of the capacitor circuits are controllable either individually or in a group to vary the voltage into the output transformer.

In some embodiments, a capacitance of a capacitor circuit is between 3.3 uF and 10 uF.

In some embodiments, the system comprises a first capacitor circuit, and two additional capacitor circuits configured to be controlled.

In some embodiments, the two additional capacitor circuits are configured to be controlled remotely. In some embodiments, the electrical stimulus circuit comprises a capacitor feedback to allow the microcontroller to determine the variables of the capacitor pulse, so as allow the microcontroller to control one or more of; charge time of the capacitor; discharge the capacitor; activate additional capacitors to the electrical stimulus circuit; change one or more of the amplitude, period, and frequency of the capacitor pulse; and change the number of pulses to form the electrical stimulus.

In some embodiments, the capacitor feedback makes the system a closed loop feedback system.

In some embodiments, the system comprises one or more feedback loops.

In some embodiments, the variables are the voltage, and current.

In some embodiments, the output transformer increases the voltage received from the capacitor circuits.

In some embodiments, the increase is between 400 volts to 29600 volts.

In some embodiments, the output transformer is less than 27 cm3 in volume.

In some embodiments, the output transformer is less than 40 mm×40 mm in width and depth, and preferably less than 30 mm×30 mm in width and depth.

In some embodiments, the output transformer is less than 40 mm, less than 30 mm, or preferably less than 20 mm in height excluding its legs.

In some embodiments, the output transformer is 17 mm in height, excluding the legs.

In some embodiments, the output transformer is cuboid in shape.

In some embodiments, the output transformer when charged is always operated in its fully saturated region.

In some embodiments, the output transformer when charging is fully saturated.

In some embodiments, the output transformer's knee point is located at approximately 20 amperes and approximately 6 kV.

In some embodiments, the output transformer receives current above its excitation knee point current.

In some embodiments, the output transformer receives a current of between 30 and 80 A.

In some embodiments, the output transformer receives a current of approximately 50 A during each capacitor pulse.

In some embodiments, the output transformer receives between 400 to 800 volts.

In some embodiments, the output transformer, when discharging across an animal in use, operates in an inefficiency range of 50 to 80%.

In some embodiments, the energy received by the output transformer is between 0.1 and 1 J.

In some embodiments, the energy received by the transformer is 0.5 J, and the energy output by the transformer is 0.1 J.

In some embodiments, the system comprises an electrical stimulus confirm feedback.

In some embodiments, the electrical stimulus confirm feedback is configured to confirm whether the electrical stimulus was successfully applied to the animal.

In some embodiments, the electrical stimulus confirm feedback comprises a shunt resistor electrically connected to each electrode that measures current across them.

In some embodiments, if the measured current across the said shunt resistor is above a set value of amps, an electrical stimulus will be confirmed as delivered.

In some embodiments, if the measured current across the said shunt resistor is below the set value of amps, an electrical stimulus will be confirmed as failed.

In some embodiments, the set value of amps is between 2 and 6, and preferably 4.

In some embodiments, if the electrical stimulus confirm feedback confirms an electrical stimulus was not delivered, the microcontroller resends an electrical stimulus.

In some embodiments, the system is a closed loop.

In some embodiments, the electrode pair is in conductive contact, or close to conductive contact, with the animal.

In some embodiments, the electrode pair comprises a positive and negative electrode spaced a distance apart, and are configured to receive part of an animal in between.

In some embodiments, the distance apart is between 50 mm and 300 mm, and preferably between 90 and 200 mm.

In some embodiments, each electrode is a strip electrode configured to complement a contour of the animal's neck.

In some embodiments, the positive electrode is located on the wearable device so as to be located on an opposing side of the animal's neck to the negative electrode.

In some embodiments, the at least one electrode of the electrode pair, and preferably both, comprise a flush surface to lay against an animal in use.

In some embodiments, the distance apart is dependent on the width of the animal's neck.

In some embodiments, the electrodes are spaced offset from the skin of the animal.

In some embodiments, the electrodes sit on the hair of the animal.

In some embodiments, the electrical stimulus circuit is configured to supply an electrical stimulus capable of jumping the animal's hair.

In some embodiments, the electrode or electrodes are configured as pins or knobs.

In some embodiments, the system comprises a fail-safe circuit configured to prevent multiple electrical stimuli being delivered simultaneously with a short or no time period in between them.

In some embodiments, the fail-safe circuit comprises a high pass filter to allow only one pulse to be delivered at a time to an animal.

In some embodiments, the boost transformer operates in the linear region of saturation.

In some embodiments, the wearable device is a collar configured to locate at least partially about the animal's neck.

In some embodiments, the animal is a type of bovine.

In some embodiments, the animal is a cow.

In some embodiments, the energy source is a battery.

In some embodiments, the battery is charged by solar panels.

In some embodiments, the system comprises solar panels.

In some embodiments, the collar houses the solar panels.

In some embodiments, the wearable device comprises a housing configured to hold the system, and solar panels.

In a further aspect, the invention resides in an animal stimulus collar, the collar configured to apply an electrical stimulus to an animal, the collar comprising;
A. an energy source to supply energy source energy at less than 10 volts;
B. a stimulus circuit housed within the collar configured to step up the energy source voltage via a boost transformer and a pulse output transformer, the boost transformer operating in an inefficient non-saturated range and delivering between 400 to 800 volts to a capacitor bank configured to increase the amperes of said energy source energy to over 50 amps to be delivered the output transformer configured to increase the boost transformer voltage to a stimulus voltage range between 10 kV and 30 kV whilst fully saturated,
C. two electrodes extending towards or adjacent the animal in use, the output transformer configured to discharge said stimulus voltage across the electrodes and hence the animal in use, and
D. a microcontroller configured for activating said stimulus circuit to supply the electrical stimulus to the animal when required.

Other aspects of the invention may become apparent from the following description which is given by way of example only and with reference to the accompanying drawings.

Other aspects of the invention may become apparent from the following description which is given by way of example only and with reference to the accompanying drawings.

In this specification where reference has been made to patent specifications, other external documents, or other sources of information, this is generally for the purpose of providing a context for discussing the features of the invention. Unless specifically stated otherwise, reference to such external documents is not to be construed as an admission that such documents, or such sources of information, in any jurisdiction, are prior art, or form part of the common general knowledge in the art.

It is also to be understood that the specific devices illustrated in the attached drawings and described in the following description are simply exemplary embodiments of the invention. Hence, specific dimensions and other physical characteristics related to the embodiments disclosed herein are not to be considered limiting.

It is acknowledged that the term “comprise” may, under varying jurisdictions, be attributed with either an exclusive or an inclusive meaning. For the purpose of this specification, and unless otherwise noted, the term ‘comprise’ shall have an inclusive meaning, allowing for the inclusion of not only the listed components or elements, but also other non-specified components or elements. The terms ‘comprises’ or ‘comprised’ or ‘comprising’ have a similar meaning when used in relation to the system or to one or more steps in a method or process.

As used hereinbefore and hereinafter, the term “and/or” means “and” or “or”, or both.

As used hereinbefore and hereinafter, “(s)” following a noun means the plural and/or singular forms of the noun.

As used hereinbefore and hereinafter, the term “About” means substantially or within a variation or tolerance one of ordinary skill in the art would typically expect to measure in the context of an electrical circuit. For example, an electronic component may be characterised at a value +/−1, 2, 5, 10 or 20% depending on a tolerance selection by the circuit designer. About X therefore reflects a variation of X=+/−1, 2, 5, 10 or 20% depending on the level of component precision a circuit may require. A measurement of a pulse characteristic of “about X” may in turn reflect a variation one of ordinary skill in the art would typically expect to be created from such a variation in component tolerance and even variations in environmental parameters, such as temperature, in so far as those parameters may cause such variation.

When used in the claims and unless stated otherwise, the word ‘for’ is to be interpreted to mean only ‘suitable for’, and not for example, specifically ‘adapted’ or ‘configured’ for the purpose that is stated.

For the purpose of this specification, where method steps are described in sequence, the sequence does not necessarily mean that the steps are to be chronologically ordered in that sequence, unless there is no other logical manner of interpreting the sequence.

The entire disclosures of all applications, patents and publications, cited above and below, if any, are hereby incorporated by reference.

### BRIEF DESCRIPTION OF THE DRAWINGS

Preferred embodiments of the invention will be described by way of example only and with reference to the drawings, in which:

FIG. 1: shows a simplified schematic view of a first circuit embodiment.

FIG. 2: shows a simplified schematic view of a second circuit embodiment.

FIG. 3: shows a simplified schematic view of a third circuit embodiment.

FIG. 4: shows a simplified schematic view of a fourth circuit embodiment.

FIG. 5: shows a more detailed view of the fourth circuit embodiments of FIG. 4.

FIG. 6: shows a theoretical graph of a transformer showing linear and saturation region.

FIG. 7: shows a simplified timeline of the capacitor charging and discharging over time.

FIG. 8: shows a graph of transformer operation exemplifying linear and saturated states.

FIG. 9: shows a graph of the transformer operation

FIG. 10a: shows a side view of a transformer of the preferred embodiment.

FIG. 10b: shows a bottom view of a transformer of the preferred embodiment.

FIG. 11: shows an animal, cow, wearing a wearable device of the present invention.

FIG. 12: shows a wearable device of the present invention.

### DETAILED DESCRIPTION

With reference to the above drawings, in which similar features are generally indicated by similar numerals, an electrical stimulus system according to a first preferred embodiment of the invention is generally indicated by the numeral 1.

### Overview

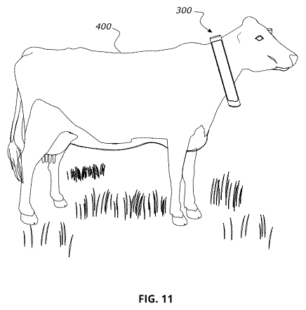

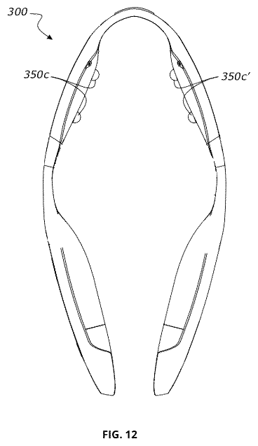

The present invention relates to an electrical stimulus system for a wearable device for an animal. The wearable device must be lightweight and have a small height, and/or volume. For context, FIG. 11 depicts an illustration of an animal 400 with an exemplary wearable device 300. FIG. 12 shows the exemplary wearable device 300 including stimulus electrodes 350c and 350c′. The stepped-up secondary voltage is released through electrical stimulus electrodes 350c,c′ to deliver an electrical stimulus to the animal 400.

The weight and volume of any wearable device is dictated by the component parts required to perform the desired functions of the device. The wearable device includes a stimulus circuit, and a particular component in a wearable animal electric stimulus circuit which contributes greatly to the size and weight of the output transformer. The output transformer is configured in a stimulus circuit to transform a small voltage into a larger voltage. Since wearable devices for animals are typically powered by a battery having a small voltage (typically 3-30 V), the function of the transformer is to transform that small voltage into the thousands of volts needed for animal stimulus. However, transformers designed for this function are typically large in volume and weight, and expensive to manufacture. These factors dictate that the wearable device will also be large in volume and weight. Exemplary embodiments of the invention discussed herein enable in the very low weight and low volume stimulus circuit that still achieves voltage and energy suitable for delivery to an animal as a stimulus. To achieve very low weight and low volume, specific components have been optimized and work together in a way that is counter to teaching in the art.

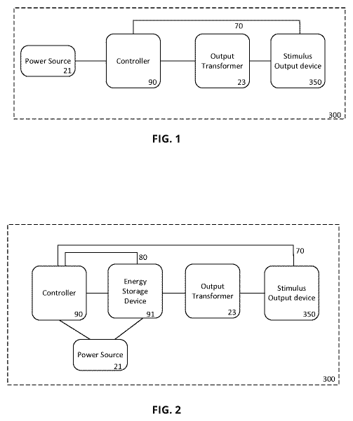

FIGS. 1 to 4 show exemplary schematic diagrams of stimulus circuits configured for use within the electronic system of an animal wearable device. In each exemplary circuit, there is an output transformer 23 configured to generate and deliver a high voltage stimulus signal. Other components in the circuit are optimised to function with particular operating characteristics that enable miniaturisation of the output transformer. By reducing the volume and weight of the output transformer, the wearable device will also be smaller and lighter.

FIG. 6 shows a theoretical graph of a general transformer showing linear and saturation regions. In the linear region, the transformer operates efficiently by converting almost all input energy into output energy. In the saturation region, a transformer will operate inefficiently and convert increasing amounts of input energy into heat. Conventional transformer operation is to operate the transformer substantially within the linear region by input of a pulse of current which is designed to match the linear region of the transformer. This means the peak of the pulse input to the transformer will peak at or near the saturation point of the transformer. To achieve a greater output from the transformer, the physical characteristics of the transformer need to also be greater.

Embodiments of the invention are configured to allow a transformer to operate substantially within the saturation region. Ordinarily, this means substantial input energy is converted to heat which in turn leads to damage to the transformer, and ultimately component failure. However, embodiments of the invention are configured to control the release of energy to the transformer operating in the saturation region such that component failure is avoided.

FIG. 1 shows a first exemplary circuit system 300 which includes a power source 21, a controller 90, an output transformer 23, and an output stimulus device 350. In some embodiments, the controller is configured to receive a feedback signal 70 from the stimulus output device such that controller functions can be optimised from a closed loop control. The exemplary circuit is operated by the controller 90 which functions to control current flow from the power source 21 to the output transformer 23. The output transformer 23 is configured to step-up any voltage applied to an input, and transform that input voltage to a larger voltage. The larger voltage is in turn output to the stimulus output device 350. The output stimulus device 350 is typically a pair of electrodes positioned to effectively transfer the output voltage to the animal.

In the exemplary circuit of FIG. 1, the controller is configured to control the release of energy from the power source 21 to the output transformer 23. In particular, the controller is configured to control energy applied to the output transformer such that the energy transformation provided by the transformer is substantially within the saturation region of the transformer.

In the exemplary circuit of FIG. 1, there are near-instantaneous energy demand requirements on the power source 21. To support the energy demand, the battery type must meet those requirements. For application in an animal stimulus device, a suitable battery type may be LiFePO chemistry or similar. Further, the controller 90 is configured to control the release of energy from the power source 21 to the output transformer. Variable power regulation of this kind typically involves operating a solid state switching device in variable conduction state, and this may generate unwanted heat.

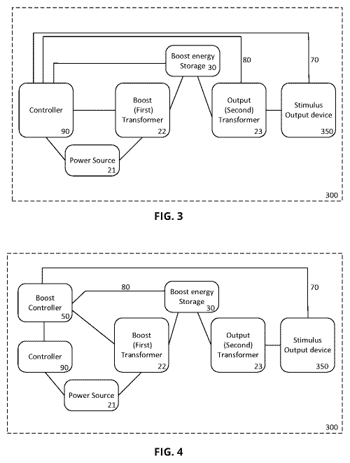

FIG. 2 shows a further exemplary circuit which may offer further advantages. In particular, FIG. 2 shows a second exemplary circuit system 300 which includes a power source 21, a controller 90, an energy storage device 91, an output transformer 23, and an output stimulus device 350. In some embodiments, the controller is configured to receive a feedback signal 70 from the stimulus output device such that controller functions can be optimised from a closed loop. In some embodiments, the controller is configured to receive a feedback signal 80 from the energy storage device 91 such that controller functions can be optimised from a closed loop control.

The energy storage device 91 device operates to store a portion of energy originating in the power source 21. The energy storage device 91 is preferably implemented by one or more capacitors, and the controller is configured to control the charging and discharging instances of the one or more capacitors. Capacitors typically have a much higher rate of discharge than a battery, and for this reason, the energy storage device 91 is configured to relieve the instantaneous energy demand from a battery. This in turn means the battery type is ideally one offering a low C rating and higher energy density. For example, a Li-Ion type battery may be most suitable for use in such a wearable device. In some embodiments, the energy storage device 91 comprises two or more capacitors configured in parallel, and the controller is configured to independently control at least the discharge of each of the two or core capacitors. In this way, the voltage output and discharge supplied by the two or more capacitors can be temporally controlled.

FIG. 3 shows a further exemplary circuit which may offer further advantages in ease of generating high voltage from low voltage power source. In particular, FIG. 3 shows a second exemplary circuit system 300 which includes a power source 21, a controller 90, a boost (first) transformer 22, a boost transformer energy storage device 30, an output (second) transformer 23, and an output stimulus device 350. In some embodiments, the controller is configured to receive a feedback signal 70 from the stimulus output device such that controller functions can be optimised from a closed loop. In some embodiments, the controller is configured to receive a feedback signal 80 from the boost energy storage device 30 such that controller functions can be optimised from a closed loop control. The boost (first) transformer 22 allows energy from the power source to be stepped up to a first high voltage and stored for use by the output (second) transformer 23.

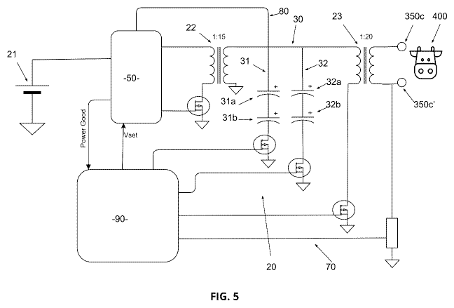

FIG. 4 shows a further exemplary circuit which may offer further advantages where high voltage generation control functions are performed by a dedicated boost controller 50. In such circuit configurations, the boost controller 50 is a separate integrated circuit configured to manage operation of the first and second transformers, and operate with closed loop control based on feedback signals from the boost transformer energy storage device 80 and stimulus output device 70. In some embodiments, the controller 90 is configured to output operation parameters to the dedicated boost controller 50. The operation parameters may be based on information relating to the state of the animal, location and other data.

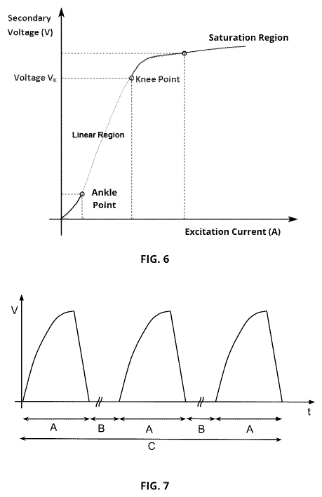

FIG. 5 shows a more detailed exemplary circuit configuration based on the schematic shown in FIG. 4. In particular, the circuit utilises the first transformer 22 to step up the energy source 21 voltage to a first voltage. The first voltage is stored in one or more electrolytic capacitors 31a, 31b, 32a, 32b in a capacitor circuit 30 that is configured to release energy to a second step-up output (second) transformer 23.

The following description is provided with specific reference to components of the circuit embodiment shown in FIG. 5, however, the principles of operation may apply to any of the other exemplary circuits described above.

### Transformer

### Pulse Times

Preferred embodiments of the invention utilise a pulse transformer for the output transformer 23. The input energy is provided to the output transformer as a pulse waveform. In one embodiment, the electrical stimulus to the animal 400 is delivered in three short pulses, up to every 10 seconds. In one embodiment, a pulse has a length of 0.1 ms (time period A as shown in FIG. 7), with a 200 ms gap (time period B as shown in FIG. 7) between each pulse. This gives an electrical stimulus length time period C of 0.403 seconds. The electrical stimulus period may occur every 10 seconds. The pulse waveform is shown in FIG. 7. The electrical stimulus pulses are similar in period and frequency to the capacitor's pulses that are delivered to the output transformer 23. However, the voltage amplitude of the electrical stimulus pulses is far higher. The capacitor pulses and thus the electrical stimulus pulses may be varied depending on the topology of the circuit, such as the capacitor and transformer selection. Further, the capacitor pulses and electrical stimulus pulses may change depending on the required electrical stimulus delivery time. For example, if the electrical stimulus delivery time is longer, more pulse may be added, or the delivery of the pulse can be changed. For example, there may be between 2 and 6 pulses per electrical stimulus.

### Saturation and Inefficiency

The output transformer 23 is operated far into the saturation region as shown in FIG. 6. This is not a common use case for a transformer due to the highly inefficient nature of the voltage conversion. A description of the saturation of transformers is found on the website All About Circuits—practical considerations of transformers, of which a modified excerpt is taken here.
Transformers are constrained in their performance by the magnetic flux limitations of the core. For ferromagnetic core transformers, we must be mindful of the saturation limits of the core. Ferromagnetic materials cannot support infinite magnetic flux densities: they tend to “saturate” at a certain level, this is dictated by the material and core dimensions, meaning that further increases in magnetic field force do not result in proportional increases in magnetic field flux. When a transformer's primary winding is overloaded from excessive applied voltage, the core flux may reach saturation levels during peak moments of the applied pulse. If this happens, the voltage induced in the secondary winding will no longer match the wave shape as the voltage powering the primary inductor. In other words, the overloaded transformer will distort the waveshape from primary to secondary windings. This typically causes problems. For most transformers, core saturation is a very undesirable effect, and it is avoided through good design: engineering the windings and core so that magnetic flux densities remain well below the saturation levels.

However, the present invention electrical stimulus system 1 is configured to operate the output transformer 23 well into its saturation region for every pulse, and every time an electrical stimulus is required to be delivered to an animal 400.

Fence energisers of the prior art use larger transformers than those in the present invention as they are cheaper and more efficient. The fence energiser transformer may use a core material worse for efficiency, but the transformer can be much larger to compensate for this inefficiency. Larger fence energiser transformers are more efficient due to their size. The fence energiser transformer needs to be efficient to keep the manufacturing and running cost low, in exchange the size of the transformer is large. The size factor is not important as the fence energiser is only mounted to a wall or similar, and does not need to be portable or carried by an animal 400.

The present invention utilises an output transformer 23 much smaller in size. Because of this small size, the output transformer runs in an inefficient area of the transformer performance. This small size can lead to large inefficiencies as described briefly previously.

### Symptoms of Saturation

Operating the output transformer 23 in the fully saturated and least efficient region is contrary to the teaching of those skilled in the art. These inefficiencies may lead to one or more of
a) excess heat which can be detrimental to circuitry and power use. It was determined that using excess power overcame any losses, and those losses could be tolerated.
b) residual magnetic field. A residual magnetic field or excess residual magnetic field can knock out magnetometer measurement. An incorrect or knocked out magnetometer measurement can be disastrous for virtual fence collars which rely heavily on the accuracy of the magnetometer for animal position and location determination. As such, the operation of a fully saturated transformer leads further away from teaching in the art. However with a very low capacitor pulse frequency, the output transformer 23 has time to let the magnetic field decay, and thus no visible losses are apparent between pulses of an electrical stimulus, and between electrical stimulus. Thus residual magnetic field issues have been able to be overcome with this unique application use.
c) loss of energy which means more energy must be input to get the desired output. The capacitors have been sized accordingly to achieve the amount of energy required after losses. Large trade-offs have been taken with the capacitors also to achieve the high amps required but still retain a lightweight design.
d) loss of dielectric strength which is the resin (or similar) material between the two inductors. Loss of strength means the insulative properties can break down, typically due to air bubbles in the resin, as such resistance decreases. However, this is unlikely to occur as the system 1 duty cycle (DC) is very low. In one embodiment, the DC is 2%, for example, over five years. The present system can tolerate the output transformer 23 running at full saturation as the wearable device 300 is required to produce far fewer electrical stimuli compared to a typical fence energiser transformer. In the worst-case theoretical scenario, the present system may need to supply 100 electrical stimuli a day, which is only around four per hour. This number of electrical stimuli is nowhere near the one or so every second required for an electric fence energiser. It was determined through testing that dielectric material would not fail in the worst case scenario.
e) burn out of the secondary winding wire. Burn out of the wire may occur because the wire is, for example, around 0.1 mm diameter and is running at, for example, 8 amps. Similar to loss of dielectric strength, burnout is unlikely to occur as the duty cycle (DC) is very low. The preferred DC is 2%, for example, over five years. It was determined through testing that the wire would not burn out in the worst-case scenario.

### Specific Details of Saturation

As discussed, the output transformer 23 is operated at full saturation. The output transformer 23 operates substantially in the linear portion (between the ankle point and knee point as shown in FIG. 6 of the transformer, and operates substantially within the plateaued portion deep into the saturated region. FIG. 8 indicates a portion of the output pulse energy which is delivered by the transformer operating in the linear or unsaturated region (time period D), and the portion delivered by the transformer operating in the saturated region.

The approximate knee point of one embodiment of a preferred output transformer 23 during normal operating conditions is at 1 A and 1 kV. However, in said embodiment, the system 1 is delivering 60 A and 600V to the second transformer 23. Due to the far higher current being received, the output transformer 23 operates heavily saturated.

Where the term ‘operates’ has been used with respect to the output transformer operating in the saturated region, it refers to when the transformer is receiving an operable current, and not between pulses or between electrical stimulus periods.

The output transformer 23 is operated in a substantially saturated state as the electrical stimulus circuit 20 is supplying to the output transformer 23 much more energy than the output transformer 23 can efficiently transform. The high energy input supplements lost energy due to the output transformer 23 being very small and losing a lot of energy during the voltage step-up process. For example, the output transformer 23 may have an inefficiency of 50%-95%.

For example, in one embodiment, there is 60 A and 600V (36000 VoltAmps) at the primary inductor and at the secondary inductor, there is 2 A and 12 kV (24000 VoltAmps) when discharging. As such, the output transformer 23 has lost 12000 VA. This is normally unacceptable inefficiency, but the system 1 compensates for this by delivering more energy to the primary side, to get the desired output at the secondary side.

In another example, the output transformer 23 has an efficiency of 8%, so as to be able to deliver 0.15 J to the animal 400.

In another example, the desired output energy of the output transformer 23, is 0.1 Joules. To achieve the desired output energy, 0.5 J is supplied to the primary inductor to get the desired output energy of 0.1 J, representing an output transformer efficiency of about 10%, or an inefficiency of about 90%.

The output transformer 23 will leave the saturation region after each capacitor pulse. After each capacitor pulse, there would likely be a little residual magnetic field in the core due to the hysteresis effect. However, after each pulse, it comes back almost to a zero point on the hysteresis curve. This is due to the low frequency of the system 1, i.e 3 pulses in around half a second. This is a far lower frequency compared to other use cases of pulse transformers.

In some embodiments, operation of the output transformer 23 is characterised by any one or more of the following operational parameters:
up to 90% of the output pulse energy generated by the transformer operating in a saturated state;
up to 85% of the output pulse energy generated by the transformer operating in a saturated state;
up to 80, 75, 70, 65, 60, 55, 50, 45, 40, 35, or 30% of the output pulse energy generated by the transformer operating in a saturated state;
the output pulse output pulse energy is up to 50% of the pulse energy input to the output transformer;
the output pulse output pulse energy is up to 55, 60, 65, 70, 75, 80, 85, 90 or 95% of the pulse energy input to the output transformer;
the output pulse output pulse energy is 0.1 J and the input pulse energy is 0.5 J;
the output pulse output pulse energy is 0.1 J and the input pulse energy is at least 0.5, 0.55, 0.6, 0.65, 0.7, 0.75, 0.8, 0.85, 0.9 or 0.95 J;
at least 50% of the pulse width generated by the output transformer operating with an efficiency of 50% or less;
at least 55, 60, 65, 70, 75, 80, 85, 90 or 95% of the pulse width generated by the output transformer operating with an efficiency of 50% or less;
the primary winding of the output transformer receives about 60-80 A, and the secondary winding outputs about 3 A;

### Details of the Transformers

### Output Transformer

The below specifications are for one use case of the output transformer 23 in the circuit configuration shown in FIGS. 4 and 5. However other specifications of the output transformer 23 may fall within the scope of the invention. The specifications below were achieved using an AT5600 or equivalent machine.
Inductance
   Primary: 1.05 mH, at 1 KHz and 1V
   Secondary: 288.28 mH at 1 KHz and 1V
DC Resistance (@20° C.):
   Across primary inductor: 1.455Ω MAX.
   Across secondary inductor: 85.6Ω MAX.
Withstand Voltage:
   P/S: AC current at 10 kV for 2 sec
   Cut off current <3 mA
Weight 19.45 g
Type: Pulse transformer
Voltage turn ratio: 1:20.

Dimensions: In one specific embodiment, the output transformer 23 is 23.5×29.5 mm wide and 15.5 mm (10.74 cm³) high excluding legs. A slightly taller model is shown in FIG. 10. Height is more controllable as it is hard to make a low and flat transformer. A low height and small weight are critical as it allows the wearable device 300 to be small and lightweight. At 10.74 cm³, and 150 millijoules, the output transformer has an energy density of at least 13.9 mj/cm³. At 19.45 g and 150 millijoules, the output transformer has an energy density of at least 7.7 mj/g.

In one embodiment, the primary wire of the primary inductor of the output transformer 23 has about 0.5 mm diameter and the secondary wire of the secondary inductor of the output transformer 23 has about 0.1 mm diameter.

TABLE 1
Experimental characteristics
of output transformer

| | | | | | Peak |
|---|---|---|---|---|---|
| | | | | Peak | open |
| | Input | Output | Peak | Load | circuit |
| Load | capacitance | Energy | current | voltage | voltage |
| (Ohms | (uF) | (mJ) | (A) | (kV) | (kV) |
| 400 | 10 | 152 | 4.5 A | 1.8 kV | 14 kV |

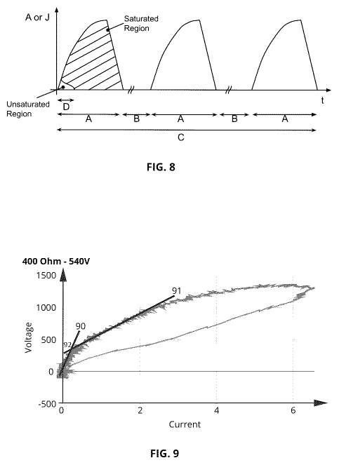

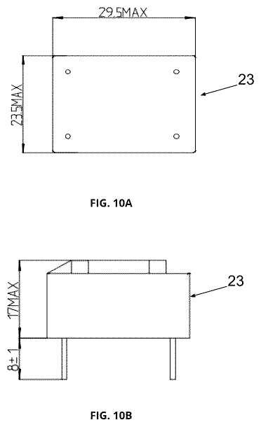

FIG. 9 shows a graph of output voltage and current, representing pulse energy and indicative of the efficiency of the above described output transformer operation. The graph data was generated using a 400 ohm ‘ideal’ load to simulate nominal real world conditions. The data points of the graph first span from left to right, then once the apex is reached, the data falls back to zero as the transformer field collapses. In particular, it can be observed that the energy conversion at the start of the pulse is substantially linear, as indicated by gradient line 90. Also observable is the initial linear gradient changes to a shallower slope of the saturated operating condition as indicated by gradient line 91 and beyond. Where the first and second gradient lines intersect is an approximate indication of the knee point of the transformer operation. As substantial data points are located to the right of the knee 92, it can be observed that substantial pulse energy is located beyond the linear region of the transformer, and within the saturated region.

The data of FIG. 9 shows the knee located at about 200V and 0.2 A. As the pulse reaches about 1300V and 6 A, the total energy of the pulse in the saturated region of operation is about 85% of the total pulse energy. If the transformer were operating in the linear region, the first indicative gradient indicates a much higher voltage would have been achieved. Those skilled in the art will appreciate that pulse energy is one feature characterising transformer operation, and other factors such an pulse energy, transformer efficiency, input and output voltage or current ratios, and other parameters may also express operation of the transformer in a saturated, or beyond the knee, state. Those skilled in the art will further appreciate that transformers are conventionally operated below, or up to the knee point, not beyond, or substantially beyond as presented by embodiments of the invention.

### First/Boost Transformer

In one embodiment, the voltage turn ratio of the step-up first transformer 22 is 1:15. The first transformer 22 is a typical flyback transformer, operating at ˜>90% efficiency. In one embodiment, the input is AC 2 A (up to 8 A) and 4V (a battery voltage is typically between 3 and 4.2). The first transformer 22 steps this to 50 mA and 600V. In one embodiment, the input into the first transformer 22 is a sawtooth AC input from the battery 21.

The 4 volts is supplied by a power source 21, such as a battery 21. Preferably the battery 21 is charged by solar power. The battery 21 must be low weight, and preferably also low volume (i.e good specific energy density) to be carried by the wearable device 300 and hence the animal 400.

### Control of Transformers

FIG. 5 shows the controller 90 which is configured to control the operation of switches which are configured to connect components of the circuit together. In particular there is a first capacitor switch configured to connect a circuit comprising capacitors 31a,b and 32a,b to ground and therefore across the secondary winding of the first transformer 22, and a second capacitor switch configured to connect capacitors 31a,b and 32a,b to ground and therefore across the primary winding of the output transformer 23.

The controller is also configured to control switches configured to close a winding of each transformer. In particular, there is a first transformer switch configured to connect the primary winding of the first transformer to ground, and a second transformer switch configured to connect the primary winding of the output transformer to ground.

It should also be noted that the transformer switch could be configured to connect either the primary or secondary winding to be effective. It should also be noted that the configuration of capacitors could take many forms based on desired capacity and/or voltage rating. For example, the capacitors 31a,b and 32a,b could instead be a single capacitor. Similarly, the switch connected to the series connected capacitors 31a,b and 32a,b could be a single switch. Accordingly, the following description will refer to a single capacitor and signal switch for simplicity. Further, in one embodiment there may only be one capacitor circuit, i.e. 31a,b, is present and 32a,b is not present.

The controller 90 is therefore configured to control connection of the capacitors to either the first transformer and output transformer at any time. In some embodiments, the controller is configured to control the timing of connection of capacitors to either transformer in relation to the pulsed operation of each transformer. In some embodiments, the first transformer is a boost transformer, and in other embodiments it is a flyback transformer.

In one embodiment, the controller operates a first timing phase where the first transformer is connected to the capacitor, and the output transformer is disconnected. In this way, energy output by the first transformer is stored by the capacitor and not received by the output transformer. Connection, in this regard, includes a pulsed connection suitable for flyback transformer operation, over a time period where the capacitor is charged.

The controller also operates a second timing phase where the output transformer is connected to the capacitor, and the first transformer is disconnected. In this way, any energy stored in the capacitor is received by the output transformer and not the first transformer.

The controller is configured to operate the first timing phase sequentially with the second timing phase. The first timing phase is operable to store a charge in the capacitor, and the second timing phase is operable to discharge the capacitor into the output transformer and thereby generate an output pulse.

In some embodiments, the first timing phase is longer than the second timing phase. The controller is thereby configured to charge the capacitor through the first transformer over a period of time. To charge the capacitor, the controller is configured to pulse the connection of the first transformer switch, such as by PWM control, such that a DC power supply is connected with the transformer in a pseudo AC manner. For example, in one embodiment the first transformer is connected to the power source by a PWM control of the switch with around 80 kHz as a base frequency and about 50% duty. The pulse connection into the first transformer is converted to a higher voltage which is used to charge up the capacitor. During the first timing phase, the capacitor may remain connected to the first transformer whereas the first transformer may be connected only by pulsed operation of the switch.

Once the capacitor is charged to a desired level, the controller is configured to control the second timing phase wherein the first transformer is disconnected from the capacitor and the output transformer is connected. Connection of the output transformer to the capacitor may be for the duration of the second timing phase, or a pulsed connection, or selective periodic connection within the phase.

The output pulse can be controlled to a desired characteristic by selective control of the connection of the output transformer to the capacitor. For example, in one embodiment, the output pulse comprises three pulses, and the controller is configured to connect the output transformer to the capacitor three times, or to pulse the connection during three intervals, during the second timing phase. The controller is configured to switch between the first and second timing phases as desired, or as required to maintain an operable charge level in the capacitor.

In some embodiments, the controller is configured to rest the capacitor between instances where it is being charged (by the first transformer) or discharged (by the output transformer). Resting the capacitor may be achieved by ensuring the voltage on the capacitor is maintained substantially constant, i.e., is not being charged or discharged. Resting the capacitor may be important in instances where the capacitor is prone to heating during charge or discharge operation, but may be for a variety of other factors such as the environmental conditions of the circuit. Resting the capacitor can be achieved by isolating the capacitor from the circuit (opening the capacitor switch) and/or opening the transformer switches such that there is no pathway for current to flow in or from the capacitor.

In some embodiments, the system comprises only the output transformer such as outlined by FIG. 2, and therefore the system has no first transformer. The controller is configured to charge the capacitor during the first timing phase by controlling the connection of the capacitor 91 to a power source 21 while the output transformer is disconnected.

In some embodiments, the output transformer the controller is configured to operate the first and second transformers by a process which includes control the connection of the energy source to the first transformer during a first interval. Simultaneously, the controller is further configured to control the connection of the capacitor circuit to the first transformer during the first interval to store energy from the first transformer in that capacitor circuit. Further, the controller is further configured to control the connection of the capacitor circuit to the second/output transformer during a second interval; and control the connection of the electrode pair to the second transformer during the second interval to realise operation of the substantially saturated state. The substantially saturated state is achieved by operating the circuit with an output pulse energy which exceeds the capability of the transformer to operate in the linear region. The operation of the electrical circuit and characteristics of the transformer which produce the saturated state are detailed elsewhere in this specification.

The system as claimed in claim 6, wherein the connection of at least the second interval comprises a pulsed connection to thereby elicit flyback operation in the second transformer.

### Capacitors

In some embodiments, energy provided to the output transformer 23 is accumulated and stored in capacitors 31,32. As earlier mentioned, capacitors can reduce the near instantaneous high current demands on power sources by storing and supplying energy that might otherwise cause the voltage from the power source 21 to sag and in some instances, the power source to be damaged. In a preferred embodiment, there is only one capacitor in the circuit.

### Type

Fence energisers typically use film capacitors due to their high near instantaneous energy delivery performance and low internal impedance. Film capacitors are capacitors with an insulating plastic film as the dielectric, sometimes combined with paper as the carrier of the electrodes.

In one embodiment, the system utilises electrolytic capacitors 31,32, preferably aluminium based electrolytic capacitors 31,32. In other embodiments, film capacitors are used. Film capacitors are larger and heavier compared to electrolytic capacitors. In alternative embodiments, the capacitors are ceramic capacitors 31,32.

Electrolytic capacitors are not as electrically efficient as film capacitors due to having a higher internal impedance by nature of their topology. Electrical efficiency must be compromised with weight. Electrolytic capacitors are much lighter than film capacitors. Weight and size are important to the use of the electrical stimulus circuit 20 in an animal collar, as the animal collar must be lightweight and comfortable to wear. Being lightweight is desired, as heavier wearable devices have a tendency to be uncomfortable and may cause sores on an animal 400. Further, electrolytic and ceramic capacitors are cheaper than film capacitors. Electrolytic capacitors present high internal resistance and inductance relative to ceramic and film capacitors.

However, other capacitor types may be chosen based on equivalent series resistance, physical size and cost. Electrolytic capacitors may have particular advantages, but for example, if the ESR of a film cap is too low, it is known that a series resistor would mimic the slower discharge response of the higher ESR electrolytic capacitor. Albeit for an increase in cost and physical capacitor size. The benefits of the smaller capacitor would still be present no matter the capacitor type in each scenario.

In one embodiment, the capacitors are metalized polypropylene film capacitors. In a particular embodiment of the invention, the capacitor is a MPP (CBB22) series metalized polypropylene film capacitor produced by Dongguan Xionguan Electronic from China. Where the capacitor has the following characteristics:

| | |
|---|---|
| Electrodes | Vacuum evaporated metal |
| Coating | Epoxy resin coating |
| Reference Standard | IEC384-16; GB10190-1988 |
| Climatic Category | 40/105/21 |
| Capacitance Versus | 0.01 uF-3.3 uF/400 VAC |
| Rated Voltage (UR) | 0.01 uF-3.3 uf 100/250 VAC |
| | 0.01 uF-2.2 uF/630 VAC |
| Capacitance Tolerance: | M = ±20% K = ±10% J = ±5% |
| Dissipation Factor | DF ≤0.1% (at 20° C., 1 KHz) |
| Voltage Proof | 1.6*UR Unit: VAC (5 S at 20° C.) |
| Insulation Resistance | C ≤0.33 uF, IR ≥30000 MΩ; |
| | C >0.33 uF, IR*C ≥5000 S |
| | (1 minute at 20° C. and RH ≤65%) |
| Endurance | 1000 hours with 125% of rated |
| | voltage at 85° C., |
| | After the test: ΔC/C ≤5%; ΔDF ≤0.4% |
| | IR ≥50% of the specified value |
| | (20° C. 1 KHz) |

### Discharge Pulse Shape

Better film capacitors have faster discharge, and shorter pulses leading to a higher energy density in a given pulse. The system 1 ideally outputs about two or three pulses over a second, as that is a good time period to create a negative reinforcement or aversive cue for an electrical stimulus.

Where film capacitors are implemented, most have a pulse energy density too high—this may have a negative effect on the output transformer, and a negative effect on the output electrical stimulus. To counter these unwanted effects, an inductor is required to smooth out the delivered pulse so it is delivered over a longer time period, and the pulse energy is more evenly spread over the length of the pulse. However, there are some film capacitors that are operationally sufficient to use without an inductor due to higher ESR and/or higher ESL than other film capacitor types (such as the MPP (CBB22) series metalized polypropylene film capacitor described above). The output waveform is slightly shorter, however animal behavior testing indicated no real-life impact to the slightly shorter waveform.

Electrolytic capacitors 31,32 are not as efficient as film capacitors and have a slower discharge rate due to their naturally higher internal impedance, this leads to a smoother pulse and bigger period—they are ideal for delivering energy over a longer period of time, such a period as required for electrical stimulus delivery to an animal 400. This is because the capacitors present more resistance to energy storage. This means that electrolytic caps 31,32 do not need an inductor to smooth out the delivery. In one embodiment, the system makes use of an inherent disadvantage of the electrolytic capacitor to further optimise the output pulse characteristics, and reduce the circuit construction costs.

In some embodiments, to further optimise the spread of energy across the output pulse, any parallel capacitors may be sized differently such that some capacitors discharge differently than others. In some embodiments, to further optimise the spread of energy across the output pulse, any parallel capacitors may be connected to discharge into the output transformer with temporal variance. In such embodiments, the controller is configured to connect any one or more parallel configured capacitors to the output transformer based on desired discharge timing.

### Charge Time

There are many side effects of electrolytic capacitors 31, 32 which means they are very seldom used for this application. Firstly, the electrolytic capacitors 31, 32 are also not rated for the current required by the system 1. They may have high energy leakage, which in turn can cause heat. This means they can get very hot. Energy leakage in the present invention isn't a large issue as the system 1 is not storing energy for long periods of time. The electrolytic capacitors 31, 32 are able to withstand the heat as the time spent charged or charging is very short. The cumulative charging is around 100 milliseconds. Further, the time period between electrical stimulus delivery is relatively long, around 10 seconds. As such, the electrolytic capacitors 31, 32 have a chance to cool down and thus inherent disadvantages typically associated with their use are mitigated.

### Tolerance

Further, in the case where electrolytic capacitors are used, they have a large tolerance, around a 20% manufacturing tolerance due to the type of capacitors required for the low weight and volume. The 20% manufacturing is over a number of capacitors, not the tolerance of one capacitor over multiple charge cycles. However, the system 1 has been configured so that the undesirable tolerance is able to be reduced and controlled, so the actual tolerance is a lot less. The system 1 utilises leverage with voltage compensation to accommodate for the manufacturing tolerance. E.g. the system 1 is capable of driving higher energy into the circuit so that a minimum output energy is achieved, and this offsets the tolerance. The system 1 utilises a capacitor feedback circuit 80 that acts as a closed-loop feedback to adjust the energy accordingly. This is described in more detail later.

The system 1 is designed to the minimum likely capacitance, so the actual capacitance may be much higher, but the capacitor feedback 80 allows a microcontroller 90 to determine that, and thus calibration can occur, for example at the production stage. For example only, the system 1 requirement is 20 mF. The capacitors have a 10 mF capacitance plus or minus 5 mF. In one embodiment, the system 1 as shown in FIG. 5 may be configured to have four capacitors at 10 mF, so the minimum likely capacitance is 20 mF. However, the maximum likely capacitance is 60 mF. Should the capacitors actually have a capacitance of 60 mF as determined by the capacitor feedback and microcontroller 90, the input energy can be decreased accordingly via the microcontroller 90. In one embodiment, the capacitance of the capacitor circuit is 10 uF.

In one embodiment, the capacitors 31, 32 receive the 50 mA and 600V from the first transformer 22, and outputs 60-80 A during discharge to the output transformer 23. The current is accumulated in the capacitors 31,32. The system 1 in such embodiments utilises two transformers to bump up the current. Otherwise the step in current is too big and the output transformer 23 requires a very large ratio which is not pragmatic. In one embodiment, at the output transformer 23, the primary inductor receives 60 to 80 A, and at the secondary inductor, the current is 3 A.

### Storage

The electrical stimulus system 1 ‘stores’ 400-600V at the capacitors 31, 32. The output transformer 23 steps this voltage up to 12 kV. The alternative is to store higher voltage energy in capacitors, but then arcing may occur across circuit componentry. With the storage of a lower voltage and utilisation of an output transformer 23, the arcing problem may be reduced.

The electrical stimulus system 1 stores energy in capacitors 31, 32 to manage the energy easier. The electrical stimulus system 1 is configured to be able to change the energy level by turning capacitors 31,32 on and off, capacitor banks/circuits 30 on and off, and/or amend the charging time of the capacitors/banks 30. As such, the system 1 can supply appropriate electrical stimulus energy depending on the animal 400, animal behaviour, and/or other requirements.

In one embodiment, the preferred capacitance of the electrical stimulus circuit 20 is 10 microfarad, with a range of 8 microfarad to 12 microfarad.

In one embodiment, the number of capacitors 31, 32 is four capacitors 31a, 31b, 32a, 32b across two banks 31, 32. This configuration achieved the correct voltage rating. As in one embodiment, the capacitors have a 400 V rating. However, any number of capacitors may also be used depending on requirements.

Using only one capacitor may increase manufacturing costs, as the voltage rating for a single unit would need to be high. But if required for space, one capacitor could be used.

Preferably the capacitor circuits, or capacitor banks 30, are switchable. Preferably, there are two banks 31,32. In one embodiment, one bank 31 is always on, and one bank 32 is switchable. There may be up to four banks (not shown), with one or more being switchable. Ceramic capacitors may have more banks as they are smaller. However, ceramic capacitors are currently more expensive. More or less switching of the capacitor banks may be included, however switches take up more space.

In an alternative, the embodiments of FIGS. 1 and 2 do not utilise a boost transformer and/or capacitors, and instead relies on high current direct from the energy source. For example, a LiFePO 4 battery which can output a higher current than typical Li-ion (LiCoO2) batteries. These batteries may be heavier, however the tradeoff is the ability to remove a transformer and capacitors.

### Feedback Loops and Microcontroller.

The system 1 is preferably a closed-looped system. The system 1 preferably comprises two feedback loops. The one or more feedbacks allow the system 1 to a) utilise cheap and small, but low tolerance capacitors, and b) a small and operably saturated output transformer, yet still provide a reliable electrical stimulus. The one or more feedbacks are preferably controlled by a controller 90, however, analog implementations of such may also be possible. The two feedback signals and their operating characteristics are described below.

A capacitor feedback (CF) 80 measures one or more of the current, voltage, energy, capacitance; preferably voltage, located after the capacitor circuits 30 prior to the output transformer 23. In one embodiment, a boost controller 50 delivers a signal to the microcontroller 90 to say that capacitors 31,32 are charged. Preferably a voltage divider is utilised to provide a measurement for the boost controller 50.

Optionally, the CF 80 determines when the capacitors 31,32 have enough energy stored for the desired output to the animal 400.

Further, the CF 80 determines when the capacitors 31,32 are charged and they can then be discharged. A further control can then trigger the capacitors 31,32 to discharge. Control is preferably achieved via the controller 90.

System variables may be changed so that the desired capacitor characteristics and energy delivery are delivered. In one application, CF 80 is useful if animals are ignoring the electrical stimulus, and then energy can be increased or decreased accordingly. For example, summer and winter and settings when the coats of animals change.

The electrical stimulus feedback (SF) 70 is used to determine what energy was delivered to the animal 400. For example; if the animal 400 has a thick coat; environment conditions change; and/or there is a larger air gap present between the animal 400 and electrodes; then electrical stimulus may not be delivered to the animal 400 correctly. The SF 70 will determine that an electrical stimulus was not delivered correctly across the electrodes, and hence to the animal 400. Thus, next time an electrical stimulus is delivered, the system variables may be changed so that the electrical stimulus is delivered correctly. The feedback loop then repeats.

The SF 70 works via the controller 90 injecting current into a SF resistor that the boost controller 50 is measuring, the boost controller 50 steady state voltage can then differ depending on requirements via varying the current to vary the voltage.

The system variables able to be changed are, for example, one or more of:
1. the number of capacitors active in the circuit,
2. the number of capacitor pulses per electrical stimulus period,
3. the length of the time between charging and discharging the capacitor
4. energy stored in the capacitor (via time of charging).

### Microcontroller

The system variables are preferably triggered to be changed by the controller 90.

When an electrical stimulus is required, the electrical stimulus circuit 20 needs to be triggered to charge up and deliver energy to an animal 400. The microcontroller 90 is preferably used to signal the trigger to the electrical stimulus circuit 20. The microcontroller 90 receives information about when to send an electrical stimulus received from an input. The input may be a manual switch, or remote signals, or signals based on a virtual fencing algorithm.

In a preferred embodiment, the microcontroller 90 is a STM32L451VET6 manufactured by STMicroelectronics.

In a preferred embodiment, the boost controller 50 is a LM5155 non-synchronous boost controller 50 manufactured by Texas Instruments. In one embodiment, the boost controller 50 delivers a signal to the microcontroller 90 indicating capacitors 31,32 are charged.

### Requirements for Stimulation

### Voltage

A voltage is required to be conducted across the layers of the animal's 400 hair and skin. This allows current to flow through the animal 400, or at least between the electrodes 350c,c′, so that the animal 400 will feel an electrical stimulus. As the device 300 is wearable, good contact cannot be guaranteed so a minimum traversable arc gap needs to be designed in for an efficient system 1.

It is the current across the animal 400 that is felt as an electric electrical stimulus and not the voltage. In a preferred embodiment, 12 kV is required to jump any reasonable air gap between the electrode and animal 400. However, once the circuit is completed the voltage collapses to 1-3 kV (see FIG. 5).

Typically it takes 3 kV to jump 1 mm of air gap, so the voltage required depends on the air gap between the electrical stimulus electrode 350 and the skin of the animal 400. The voltage of the electrical stimulus may range, and can be altered, to between 1 kV to 30 kV, depending on the resistance between the electrodes 350, e.g. the air gap, environment conditions, and/or animal resistance.

When an animal 400 is stimulated, the voltage breaks down the non-conducting insulation layers of the animal's 400 hair and skin allowing current to flow through the animal 400 across to the other electrode to complete the circuit. The resistance of the animal 400 to the voltage will vary between 50 Ω and 2000 Ω depending on the animal 400, the current path, and the condition of the animal 400. A typical value of 400 Ω is estimated for cows.

### Energy

The energy required to give an animal 400 a memorable negative aversive cue (stimulus) is small. A large animal 400 can be given a memorable electrical stimulus with a small amount of energy. An animal electrical stimulus collar 300 delivering 0.1 Joules through the animal 400, is capable of giving a memorable electrical stimulus to a cow or similar animal 400, depending on the animal 400. A variable energy output is the most ethically ideal solution. The range of energy depends on the animal 400, and maybe between 20 mJ and 200 mJ.

### Time

An example time period for delivering an electrical stimulus to an animal 400 is between 0.4 and 1.5 seconds. This electrical stimulus time period is variable, but a good starting point for use on large animals such as cows is 0.4 sec. The electrical stimulus time period comes into play when designing the specifications of the capacitors, transformers and the delivery of the electrical stimulus pulses. There are many different research methods and theories on the electrical stimulus time period. Electrical stimulus time period may range, for example between 0.2 to 1.8 seconds, but may vary outside of these ranges depending on circumstance.

### Fail-Safe Circuit

In one embodiment, the system 1 comprises at least one safety circuit configured to prevent constant delivery of electrical stimuli. In one embodiment, this is in the form using a high pass filter.

Although outside the range of this invention, the system should have multiple fail-safes that are secure and robust. Furthermore, animal ethics and health must be taken into account when designing and operating the system. A minimal amount of electrical stimulation should be given. Preferably alternative, non-aversive cues should be given to an animal prior to receiving any negative stimulus, such as sound or vibration. To maximise animal welfare and minimise the animal's stress response, a framework guided by the cognitive activation theory of stress (CATS) may be followed. Two major factors that lead to an animal's stress response are predictability and controllability.

Where in the foregoing description reference has been made to elements or integers having known equivalents, then such equivalents are included as if they were individually set forth.

Although the invention has been described by way of example and with reference to particular embodiments, it is to be understood that modifications and/or improvements may be made without departing from the scope or spirit of the invention.

1. An electrical stimulus system for a wearable device configured to be worn by an animal, the system configured to apply an electrical stimulus to an animal, the system comprising:
a. an energy source;
b. an electrode pair;
c. an electrical stimulus circuit operable to generate the electrical stimulus from the energy source and provide the generated stimulus to the electrode pair, and comprising one or more capacitors configured to store energy for an output transformer; and
d. a controller configured to operate the electrical stimulus circuit when required,
wherein the electrical stimulus circuit is configured to generate the electrical stimulus from operation of the output transformer characterised by operational parameters representing a substantially saturated state.

2. The system as claimed in claim 1, wherein the output transformer operationally generates the electrical stimulus as an output pulse having an output pulse energy, wherein operation of the output transformer is characterised by between 30% and 80% of the output pulse energy is generated by the output transformer operating in a saturated state.

3. The system as claimed in claim 1, wherein the output transformer operationally generates the electrical stimulus as an output pulse having an output pulse energy, wherein operation of the output transformer is characterised by the output pulse energy being between 20% and 50% of a pulse energy input into to the output transformer.

4. The system as claimed in claim 1, wherein the output transformer operationally generates the electrical stimulus with an output pulse having an output pulse energy, wherein the output pulse energy is one or more of:
between 0.1 and 0.15 J and a pulse energy input from the capacitors into the output transformer is about 0.5 J; and
substantially 0.15 J and an input pulse energy input from the capacitors into the output transformer is at least 0.4, 0.45, 0.5, 0.55, 0.6, 0.65, 0.7, 0.75, 0.8, 0.85, 0.9 or 0.95 J.

5. The system as claimed in claim 1, wherein the output transformer operationally generates the electrical stimulus as an output pulse having an output pulse width, wherein operation of the output transformer in the substantially saturated state is characterised by one of:
at least 50% of the output pulse width is generated by the output transformer operating with an efficiency of 50% or less; and
at least 55, 60, 65, 70, 75, 80, 85, 90 or 95% of the output pulse width is generated by the output transformer operating with an efficiency of 50% or less.

6. The system as claimed in claim 1, wherein the output transformer comprises a second transformer and the system further comprises a first transformer, and the controller is configured to:
control the connection of the energy source to the first transformer during a first interval;
control the connection of the capacitor circuit to the first transformer during the first interval to store energy from the first transformer;
control the connection of the capacitor circuit to the second/output transformer during a second interval; and
control the connection of the electrode pair to the second transformer during the second interval to realize operation of the substantially saturated state.

7. The system as claimed in claim 6, wherein the connection of at least the second interval comprises a pulsed connection to thereby elicit flyback operation in the second transformer.

8. The system as claimed in claim 6, wherein the output transformer is configured to receive energy stored by the capacitor circuit.

9. The system as claimed in claim 6, wherein the output transformer is configured to step up the energy stored by the capacitor circuit to a range between 400V and 30 kV.

10. The system as claimed in claim 6, wherein the boost transformer increases the energy source volts to a range between 400 volts and 800 volts.

11. The system as claimed in claim 6, wherein the boost transformer operates in the linear region of saturation.

12. The system as claimed in claim 6, wherein the controller is configured to switch energy from the energy source to the first transformer, between generated stimulus, to charge the capacitor circuit.

13. The system as claimed in claim 1, wherein the energy source supplies between 20 and 40 watts, and/or 3 and 5 volts, or about 4.2 volts.

14. The system as claimed in claim 1, wherein the wearable device is an animal wearable collar comprising a housing configured to support at least the output transformer and the capacitor.

15. An electrical stimulus system for a wearable device configured to be worn by an animal, the system configured to apply an electrical stimulus, having an output pulse energy, to an animal, the system comprising:
a. an energy source;
b. an electrode pair;
c. an electrical stimulus circuit comprising one or capacitors configured to receive energy directly or indirectly from the energy source, and store and provide input energy to an output transformer, the electrical stimulus circuit operable to generate output pulse energy from the input pulse energy to the electrode pair to generate the electrical stimulus, and,
d. a controller configured to operate the electrical stimulus circuit when required; and
wherein the output transformer is configured to output between 30% and 80% of the output pulse energy in a saturated state, and the output pulse energy is between 20% and 50% of the pulse energy input into the output transformer.

16. The system as claimed in claim 15, wherein the energy source is less than 5 volts, and the output pulse energy is greater than 0.1 joules.

17. The system as claimed in claim 15, wherein the output pulse voltage is greater than 1.5 kilovolts.

18. The system as claimed in claim 15, wherein the output transformer has an energy density around 13.9 mj/cm³ and/or around 7.7 mj/g.
